(19) United States
(12) Patent Application Publication
(10) Pub. No.: US 2024/0178747 A1
(43) Pub. Date: May 30, 2024

(54) SWITCHING POWER SUPPLY, AMPLIFICATION DEVICE, AND COMMUNICATION DEVICE

(71) Applicant: Fujitsu Limited, Kawasaki-shi (JP)

(72) Inventor: Tatsuya Hirose, Yokohama (JP)

(73) Assignee: Fujitsu Limited, Kawasaki-shi (JP)

(21) Appl. No.: 18/457,671

(22) Filed: Aug. 29, 2023

(30) Foreign Application Priority Data
Nov. 30, 2022 (JP) 2022-191203

(51) Int. Cl. H02M 1/38; H02M 1/00; H02M 1/088; H02M 3/157

(52) U.S. Cl. CPC H02M 1/385; H02M 1/0025; H02M 1/088; H02M 3/157

(57) ABSTRACT

A switching power supply includes a switching power supply circuit that has an upper arm and a lower arm that are coupled in series. The switching power supply further includes a drive circuit that alternately turns on the upper arm and the lower arm across a dead time in which the upper arm and the lower arm are turned off such that an output voltage of the switching power supply circuit follows a voltage of an input signal that is an envelope signal or a subcarrier signal; and an adjustment circuit that adjusts the dead time according to the voltage of the input signal.

### CROSS-REFERENCE TO RELATED APPLICATION

This application is based upon and claims the benefit of priority of the prior Japanese Patent Application No. 2022-191203, filed on Nov. 30, 2022, the entire contents of which are incorporated herein by reference.

### FIELD

The embodiments discussed herein are related to a switching power supply, an amplification device, and a communication device.

### BACKGROUND

Since before, a synchronous rectification type switching power supply that supplies power to a power supply terminal of an amplification unit so that a voltage of the power supply terminal of the amplification unit follows an envelope voltage of a signal input to the amplification unit is known.

Japanese Laid-open Patent Publication No. 2015-41999 is disclosed as related art.

### SUMMARY

According to an aspect of the embodiments, a switching power supply includes a switching power supply circuit that has an upper arm and a lower arm that are coupled in series; a drive circuit that alternately turns on the upper arm and the lower arm across a dead time in which the upper arm and the lower arm are turned off such that an output voltage of the switching power supply circuit follows a voltage of an input signal that is an envelope signal or a subcarrier signal; and an adjustment circuit that adjusts the dead time according to the voltage of the input signal.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a diagram illustrating a configuration example of a communication device of a first embodiment;

FIG. 2 is a circuit diagram illustrating a configuration example of a step-down switching power supply;

FIG. 3 is a time chart of a clock CLK, a clock CLKbar, and an inductor current IL;

FIG. 4 is a time chart of the clock CLK, the clock CLKbar, and the inductor current IL in a case where a dead time is changed;

FIG. 5 is a configuration diagram of a switching power supply having a configuration for performing dead time control;

FIG. 6 is a timing chart of a pulse width modulation signal (PWM signal) subjected to the dead time control;

FIG. 7 is a configuration diagram of an example of a logic circuit that implements FIG. 6;

FIG. 8 is a waveform diagram exemplifying a relationship among a dead time Td, an input signal 3 (envelope signal or subcarrier signal), and an output voltage V_{OUT};

FIG. 9 is a diagram for describing a dead time adjustment function;

FIG. 10 is a diagram for describing an effect of the dead time adjustment function;

FIG. 11 is a configuration diagram of an example of a delay circuit;

FIG. 12 is a configuration diagram of an example of a waveform inversion circuit;

FIG. 13 is a configuration diagram of an example of a sample hold circuit;

FIG. 14 is a diagram illustrating a configuration example of a communication device of a second embodiment;

FIG. 15 is a configuration diagram of an example of a carrier amplifier;

FIG. 16 is a configuration diagram of a switching power supply circuit in a case where switches SW1 and SW2 are implemented by transistors;

FIG. 17 is a diagram illustrating a configuration example of a communication device of a third embodiment; and

FIG. 18 is a diagram illustrating a configuration example of a communication device of a fourth embodiment.

### DESCRIPTION OF EMBODIMENTS

In the existing technology, it may be difficult to cause an output voltage of a switching power supply circuit to follow a voltage of an envelope signal or a subcarrier signal with high accuracy.

An object of the present disclosure is to cause an output voltage of a switching power supply circuit to follow a voltage of an envelope signal or a subcarrier signal with high accuracy.

Hereinafter, embodiments will be described with reference to the drawings.

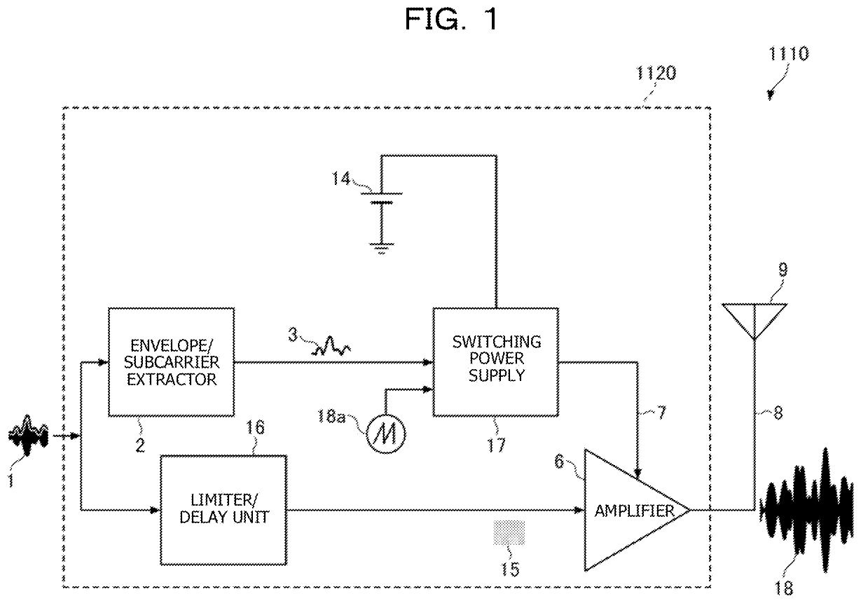

FIG. 1 is a diagram illustrating a configuration example of a communication device of a first embodiment. A communication device 1110 illustrated in FIG. 1 transmits radio waves by an antenna 9 fed by an amplifier 6 of an amplification device 1120. As specific examples of the communication device 1110, a wireless terminal device (a mobile phone, a smartphone, an Internet of Things (IOT) device, and the like), a wireless base station, and the like are exemplified. FIG. 1 illustrates a portion having a transmission function in the communication device 1110 that transmits and receives radio waves by the antenna 9. The communication device 1110 includes the amplification device 1120 and the antenna 9.

The amplification device 1120 amplifies a modulated wave 1. A modulated wave 18, which is the modulated wave 1 amplified by the amplification device 1120, is supplied to the antenna 9 via a feeder line 8. With this configuration, a radio wave corresponding to the modulated wave 1 is transmitted from the antenna 9. The amplification device 1120 includes an extractor 2, a switching power supply 17, a constant voltage power supply 14, a limiter 16, and the high-power amplifier 6.

The modulated wave 1 input from an input terminal is a carrier signal (carrier wave) modulated with a data signal including information. The modulated wave 1 is a high-frequency signal whose amplitude changes. The modulated wave 1 is branched into two directions. The modulated wave 1 branched in a first direction is supplied to the extractor 2. The modulated wave 1 branched in a second direction is supplied to the limiter 16.

The extractor 2 extracts an envelope from the modulated wave 1 and outputs an envelope signal representing the extracted envelope. The extractor 2 may extract a subcarrier signal in an orthogonal frequency division multiplexing (OFDM) system from the modulated wave 1 and output the subcarrier signal. The envelope signal or the subcarrier signal is referred to as an input signal 3.

The switching power supply 17 operates at a constant power supply voltage generated by the constant voltage power supply 14, and outputs a voltage that changes according to a voltage of the input signal 3. The switching power supply 17 has a terminal to which the input signal 3 is input, and a terminal to which a sampling signal 18a for sampling the input signal 3 and converting the input signal 3 into a pulse waveform is input. The switching power supply 17 changes the output voltage with a waveform following the input signal 3 by the input signal 3 and the sampling signal 18a. The voltage output from the switching power supply 17 is input to a power supply terminal of the high-power amplifier 6 via a power supply line 7.

The limiter 16 is a circuit that limits an amplitude of the modulated wave 1. The limiter 16 limits the amplitude of the modulated wave 1 to a predetermined upper limit value, so that a carrier signal 15 having a constant amplitude is output from the limiter 16. The carrier signal 15 having the constant amplitude is input to the high-power amplifier 6. With this configuration, since constant power is input to the high-power amplifier 6, the high-power amplifier 6 may operate around the maximum value of an output power addition efficiency curve. As a result, the high-power amplifier 6 may operate with high efficiency. Note that the limiter 16 may be replaced with a processing circuit 13 (delay circuit or equalizer) to be described later.

The high-power amplifier 6 amplifies and outputs the modulated wave 1 (the carrier signal 15 having the constant amplitude). Since the switching power supply 17 modulates a power supply voltage of the high-power amplifier 6 by using the input signal 3, the modulated wave 18 obtained by amplifying the modulated wave 1 is output from the high-power amplifier 6. With this configuration, efficiency of the high-power amplifier 6 may be improved as compared with a case where the power supply voltage of the high-power amplifier 6 is constant.

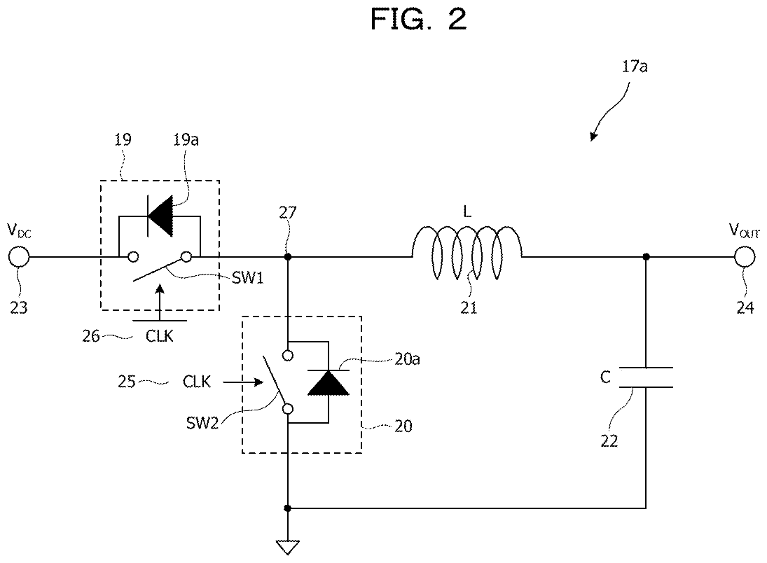

FIG. 2 is a circuit diagram illustrating a configuration example of a step-down switching power supply. A switching power supply circuit 17a is a synchronous rectification type step-down switching power supply circuit. The switching power supply circuit 17a is provided at an output stage of the switching power supply 17 described above.

The switching power supply circuit 17a includes an upper arm 19 and a lower arm 20 coupled in series, an inductor 21 having one end coupled to a coupling point 27 between the upper arm 19 and the lower arm 20, and a capacitor 22 having one end coupled to the other end of the inductor 21. The switching power supply circuit 17a includes a power supply input terminal 23 to which a constant power supply voltage V_{DC} generated by the constant voltage power supply 14 described above is input, and a power supply output terminal 24 to which an output voltage V_{OUT} is output. The switching power supply circuit 17a includes a clock terminal 26 to which a clock CLKbar supplied from the outside is input and a clock terminal 25 to which a clock CLK supplied from the outside is input.

Note that the clock CLKbar is a signal whose logic level is inverted to that of the clock CLK. Furthermore, in the drawings, “CLK” with an upper line “-” represents the clock CLKbar.

The upper arm 19 has a configuration in which a diode 19a is coupled in parallel to a switch SW1 that is turned on or off by the clock CLKbar supplied from the outside. The lower arm 20 has a configuration in which a diode 20a is coupled in parallel to a switch SW2 that is turned on or off by the clock CLK supplied from the outside. The switch is, for example, a transistor.

One terminal of the upper arm 19 is coupled to the power supply input terminal 23. A cathode of the diode 19a coupled in parallel to the switch SW1 of the upper arm 19 is coupled to the power supply input terminal 23. The other terminal of the upper arm 19 is coupled to one terminal of the lower arm 20. A coupling point therebetween is referred to as the coupling point 27. A cathode of the diode 20a coupled in parallel to the switch SW2 of the lower arm 20 is coupled to the coupling point 27. The other terminal of the lower arm 20 is grounded.

One terminal of the inductor 21 is coupled to the coupling point 27. The other terminal of the inductor 21 is coupled to the one terminal of the capacitor 22 and the power supply output terminal 24. The other terminal of the capacitor 22 is grounded. The inductor 21 has an inductance L. The capacitor 22 has a capacitance C.

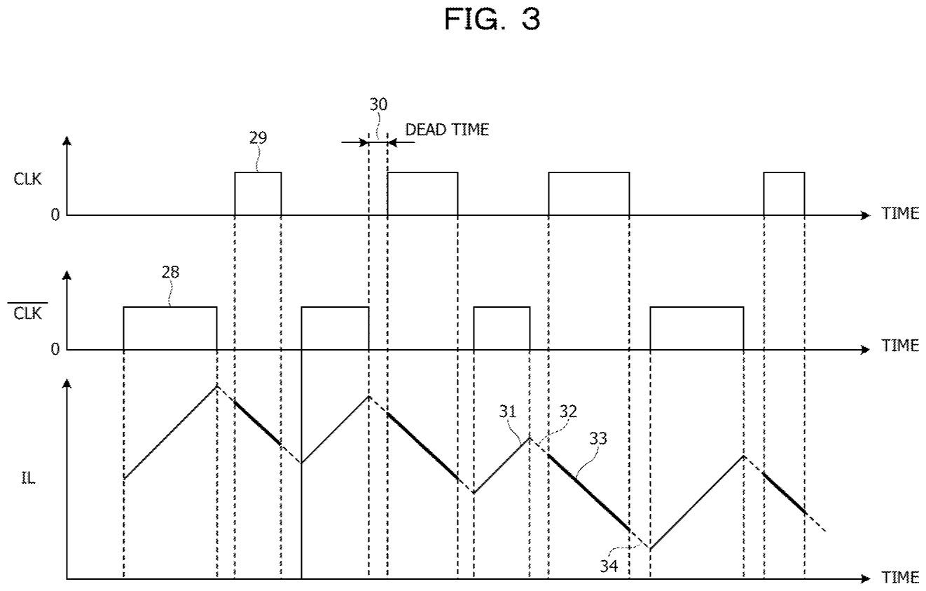

FIG. 3 is a time chart of the clock CLK for switching the lower arm 20, the clock CLKbar for switching the upper arm 19, and an inductor current IL flowing through the inductor 21. For example, when the logic level of the clock CLKbar is at a high level (in the case of a high-level pulse 28), the upper arm 19 is turned on, and when the logic level of the clock CLKbar is at a low level, the upper arm 19 is turned off. On the other hand, when the logic level of the clock CLK is at a high level (in the case of a high-level pulse 29), the lower arm 20 is turned on, and when the logic level of the clock CLK is at a low level, the lower arm 20 is turned off.

When the logic level of the clock CLKbar is at the high level, the inductor current IL that rises at a constant slope flows through the inductor 21. A dead time 30 in which the upper arm 19 and the lower arm 20 are turned off is provided in a switching period between the clock CLK and the clock CLKbar.

In an on-period of the upper arm 19, an inductor current 31 that rises at a constant slope flows. When the upper arm 19 is switched from on to off, a magnetic flux is formed in the inductor 21, so that a current may not be instantaneously cut off unlike a switch. Therefore, until the magnetic flux formed in the inductor 21 disappears, a diode current 32 tends to flow to the diode 20a according to a time constant determined by a load coupled to the capacitor 22 and the power supply output terminal 24. For example, in a first dead time from off of the upper arm 19 to on of the lower arm 20, the diode current 32 flows through the diode 20a coupled in parallel to the lower arm 20.

Next, when the lower arm 20 is switched from off to on, the diode current 32 flowing through the diode 20a is cut off, and an inductor current 33 that decreases at a constant slope flows through the switch SW2 of the lower arm 20.

Next, when the lower arm 20 is switched from on to off, the current flowing through the switch SW2 of the lower arm 20 is cut off, and a diode current 34 flowing through the diode 20a of the lower arm 20 flows. For example, in a second dead time from off of the lower arm 20 to on of the upper arm 19, the diode current 34 flows through the diode 20a coupled in parallel to the lower arm 20.

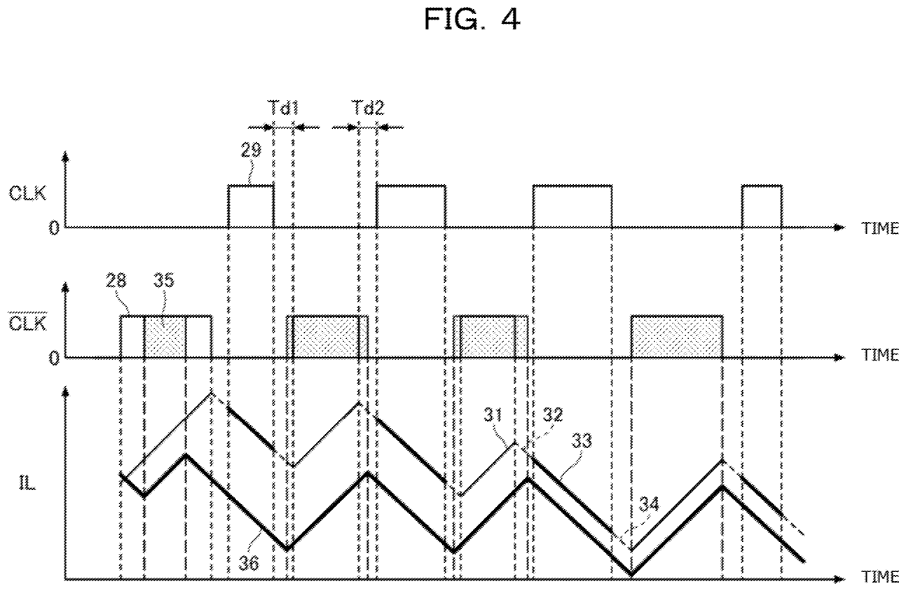

On the other hand, FIG. 4 is a time chart of the clock CLK for switching the lower arm 20, the clock CLKbar for switching the upper arm 19, and the inductor current IL flowing through the inductor 21 in a case where the dead time is changed. As illustrated in FIG. 4, by changing the dead time at a timing of generation of each of the pulses 28, a length of the pulse 28 is changed to that of, for example, a pulse 35.

For example, when a first dead time Td1 from off of the lower arm 20 to on of the upper arm 19 becomes longer, a period during which the inductor current IL that decreases at a constant slope flows through the diode 20a of the lower arm 20 becomes longer. Conversely, when the first dead time Td1 becomes shorter, the period during which the inductor current IL that decreases at the constant slope flows through the diode 20a of the lower arm 20 becomes shorter. Similarly, when a second dead time Td2 from off of the upper arm 19 to on of the lower arm 20 becomes longer, the period during which the inductor current IL that decreases at the constant slope flows through the diode 20a of the lower arm 20 becomes longer. Conversely, when the second dead time Td2 becomes shorter, the period during which the inductor current IL that decreases at the constant slope flows through the diode 20a of the lower arm 20 becomes shorter.

For example, by adjustment of one or both of the first dead time Td1 and the second dead time Td2, magnitude of the inductor current IL may be finely adjusted as illustrated in FIG. 4. Therefore, by performing control for adjustment of the dead time, it is possible to cause the output voltage V_{OUT} of the switching power supply 17 to follow the input envelope signal or subcarrier signal with high accuracy.

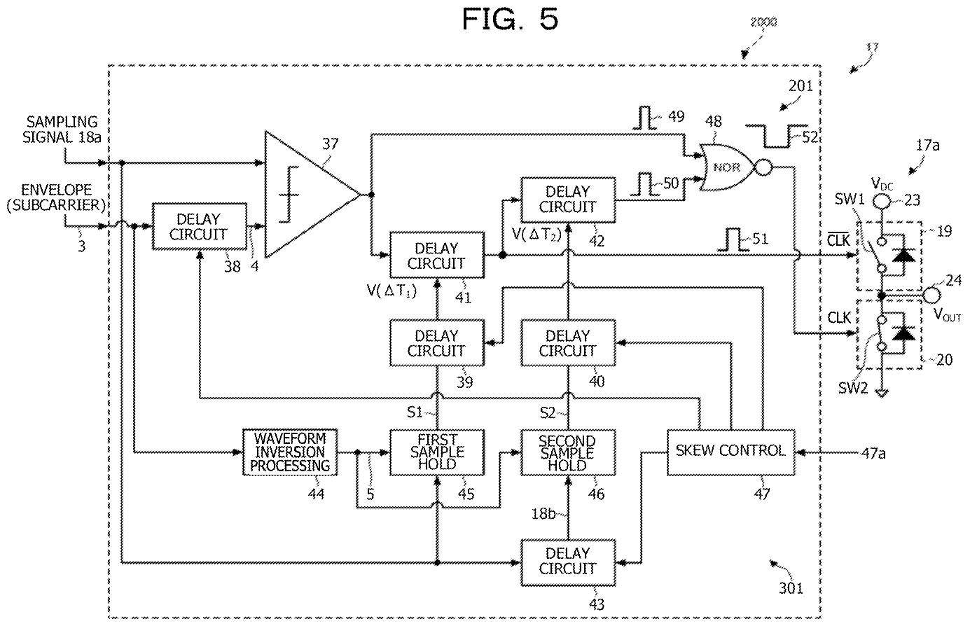

FIG. 5 is a configuration diagram of the switching power supply having a configuration for performing the dead time control. The switching power supply 17 illustrated in FIG. 5 includes a pulse width modulator 2000 capable of controlling the dead time, and the switching power supply circuit 17a that operates according to the clock CLK and the clock CLKbar generated by the pulse width modulator 2000. Note that, although the switching power supply circuit 17a has the configuration illustrated in FIG. 2, illustration of the inductor 21 and the capacitor 22 is omitted in FIG. 5. The pulse width modulator 2000 includes a drive circuit 201 and an adjustment circuit 301

The drive circuit 201 alternately turns on the upper arm 19 and the lower arm 20 across a dead time Td for turning off the upper arm 19 and the lower arm 20 such that the output voltage V_{OUT} of the switching power supply circuit 17a follows the voltage of the envelope signal or the subcarrier signal. The envelope signal or the subcarrier signal corresponds to the input signal 3 described above. The adjustment circuit 301 adjusts the dead time Td according to the voltage of the input signal 3 which is the envelope signal or the subcarrier signal.

The drive circuit 201 includes a first delay circuit 38, a comparator 37, a second delay circuit 41, a third delay circuit 42, and a negative OR (NOR) circuit 48.

The first delay circuit 38 outputs a delay input signal 4 which is a signal obtained by delaying the input signal 3 which is the envelope signal or the subcarrier signal. The first delay circuit 38 may be omitted. The comparator 37 compares the delay input signal 4 with the sampling signal 18a and outputs a first pulse signal 49 which is a pulse width modulation signal. The second delay circuit 41 outputs a second pulse signal 51 obtained by delaying the first pulse signal 49 by a first delay amount ΔT₁ corresponding to a first control voltage V(ΔT₁), and switches the upper arm 19. The second pulse signal 51 corresponds to the clock CLKbar. The third delay circuit 42 outputs a third pulse signal 50 obtained by delaying the second pulse signal 51 by a second delay amount ΔT₂ corresponding to a second control voltage V(ΔT₂). The NOR circuit 48 outputs a fourth pulse signal 52 which is a NOR of the first pulse signal 49 and the third pulse signal 50, and switches the lower arm 20. The fourth pulse signal 52 corresponds to the clock CLK.

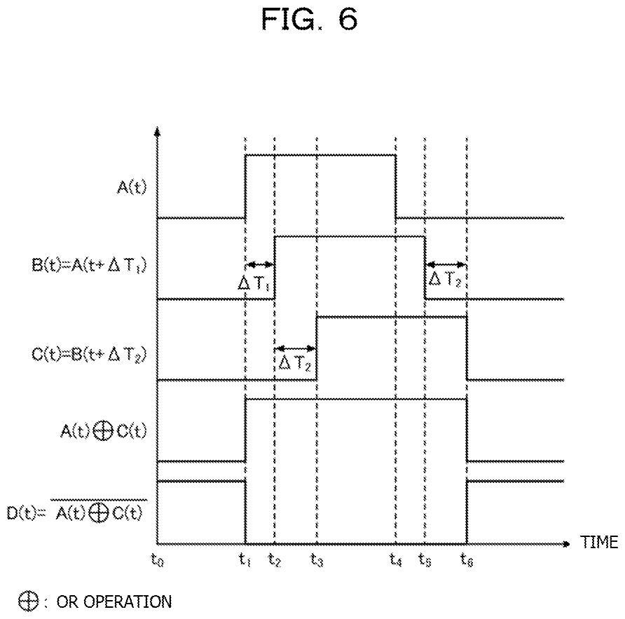

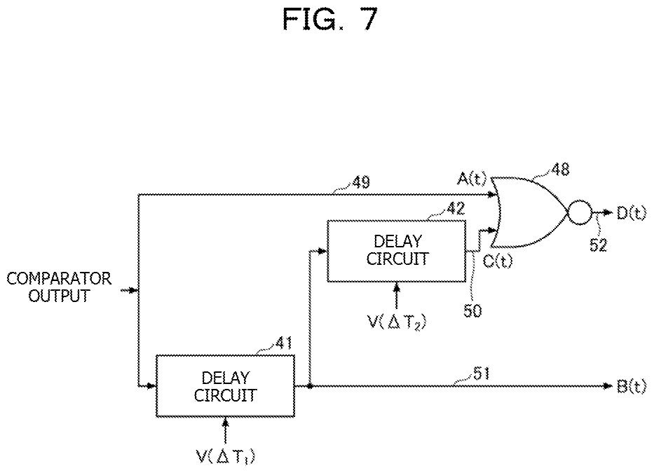

FIG. 6 is a timing chart of a pulse width modulation signal (PWM signal) subjected to the dead time control. FIG. 7 is a configuration diagram of an example of a logic circuit that implements FIG. 6. A PWM signal A(t) is a signal including the first pulse signal 49. A PWM signal B(t) is a signal including the second pulse signal 51. A PWM signal C(t) is a signal including the third pulse signal 50. A PWM signal D(t) is a signal including the fourth pulse signal 52. FIG. 6 will be described with reference to FIG. 7.

The second delay circuit 41 outputs the second pulse signal 51 obtained by delaying the first pulse signal 49 by the first delay amount ΔT₁ corresponding to the first control voltage V(ΔT₁). The PWM signal A(t) includes the first pulse signal 49, is at a low level from a time t0 to a time t1, and is at a high level from the time t1 to a time t4. The PWM signal B(t) includes the second pulse signal 51, is at a low level from the time t0 to a time t2, and is at a high level from the time t2 to a time t5.

The third delay circuit 42 outputs the third pulse signal 50 obtained by delaying the second pulse signal 51 by the second delay amount ΔT₂ corresponding to the second control voltage V(ΔT₂). The PWM signal C(t) includes the third pulse signal 50, is at a low level from the time t0 to a time t3, and is at a high level from the time t3 to a time t6.

The NOR circuit 48 outputs the PWM signal D(t) which is a NOR of the PWM signal A(t) and the PWM signal C(t). The PWM signal D(t) includes the fourth pulse signal 52, is at a high level from the time t0 to the time t1, and is at a low level from the time t1 to the time t6.

As described above, the first dead time Td1 (=the first delay amount ΔT₁) and the second dead time Td2 (=the second delay amount ΔT₂) exist between the fourth pulse signal 52 included in the PWM signal D(t) and the second pulse signal 51 included in the PWM signal B(t). Additionally, the second delay circuit 41 may increase or decrease a length of the first dead time Td1 (=the first delay amount ΔT₁) according to the first control voltage V(ΔT₁). The third delay circuit 42 may increase or decrease a length of the second dead time Td2 (=the second delay amount ΔT₂) according to the second control voltage V(ΔT₂).

In FIG. 5, the adjustment circuit 301 includes a fourth delay circuit 43, a waveform inversion circuit 44, a first sample hold circuit 45, a second sample hold circuit 46, a fifth delay circuit 39, and a sixth delay circuit 40.

The fourth delay circuit 43 outputs a delay sampling signal 18b which is a signal obtained by delaying the sampling signal 18a. The waveform inversion circuit 44 generates an inversion signal 5 which is a signal obtained by vertically inverting the input signal 3. The first sample hold circuit 45 samples the inversion signal 5 according to the sampling signal 18a, and outputs a first quantization signal S1 which is a signal obtained by quantizing the inversion signal 5. The second sample hold circuit 46 samples the inversion signal 5 according to the delay sampling signal 18b, and outputs a second quantization signal S2 which is a signal obtained by quantizing the inversion signal 5. The fifth delay circuit 39 delays the first quantization signal S1 and outputs the first control voltage V(ΔT₁). The sixth delay circuit 40 delays the second quantization signal S2 and outputs the second control voltage V(ΔT₂).

The switching power supply 17 may include a skew controller 47 that aligns operation timings of the first delay circuit 38, the fourth delay circuit 43, the fifth delay circuit 39, and the sixth delay circuit 40 according to a skew control signal 47a. By skew control by the skew controller 47, an error of the first control voltage V(ΔT₁) and an error of the second control voltage V(ΔT₂) are suppressed. By the suppression of these errors, accuracy of causing the output voltage V_{OUT} of the switching power supply 17 to follow the voltage of the input envelope signal or subcarrier signal is improved.

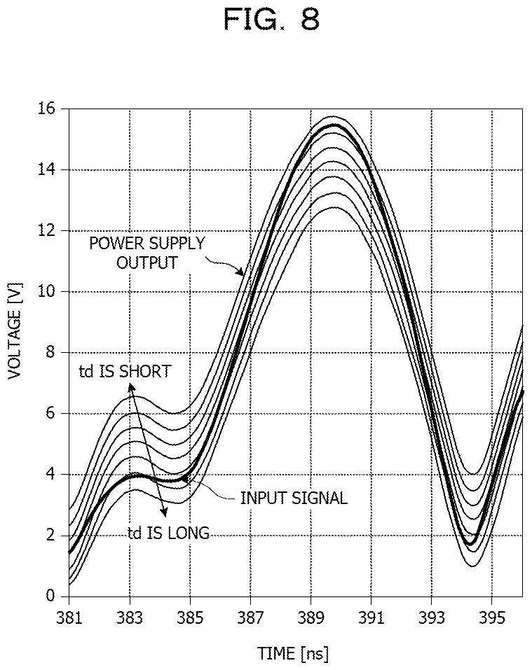

FIG. 8 is a waveform diagram exemplifying a relationship among the dead time Td, the input signal 3 (envelope signal or subcarrier signal), and the output voltage V_{OUT}. FIG. 8 illustrates a following degree between the voltage of the input signal 3 and the output voltage V_{OUT} when the dead time Td (in this case, the first dead time Td1=the second dead time Td2) is fixed at each value.

In a case where the dead time Td is relatively short, when the voltage of the input signal 3 is higher than an average voltage Va (in this example, about 8 volts) of the input signal 3, the output voltage V_{OUT} has higher accuracy of following the voltage of the input signal 3 as compared with when the voltage of the input signal 3 is lower than the average voltage Va. Conversely, in a case where the dead time Td is relatively long, when the voltage of the input signal 3 is higher than the average voltage Va of the input signal 3, the output voltage V_{OUT} has lower accuracy of following the voltage of the input signal 3 as compared with when the voltage of the input signal 3 is lower than the average voltage Va.

Focusing on this point, the adjustment circuit 301 (FIG. 5) has a dead time adjustment function of shortening the dead time Td when the voltage of the input signal 3 is higher than the average voltage Va of the input signal 3 as compared with when the voltage of the input signal 3 is lower than the average voltage Va of the input signal 3. This dead time adjustment function improves the accuracy of causing the output voltage V_{OUT} to follow the voltage of the input signal 3.

When the voltage of the input signal 3 is higher than the average voltage Va of the input signal 3, the adjustment circuit 301 shortens the dead time Td as the voltage of the input signal 3 is higher. On the other hand, when the voltage of the input signal 3 is lower than the average voltage Va of the input signal 3, the adjustment circuit 301 lengthens the dead time Td as the voltage of the input signal 3 is lower. With such a dead time adjustment function, the accuracy of causing the output voltage V_{OUT} to follow the voltage of the input signal 3 is further improved.

The dead time adjustment function shortens (decreases) the dead time Td when the voltage of the input signal 3 is high (large), and lengthens (increases) the dead time Td when the voltage of the input signal 3 is low (small). For example, by controlling magnitude of the voltage of the input signal 3 and the dead time Td to have an inverse relationship, the accuracy of causing the output voltage V_{OUT} to follow the input signal 3 is improved. In order to create this inverse relationship, the adjustment circuit 301 includes the waveform inversion circuit 44 (FIG. 5).

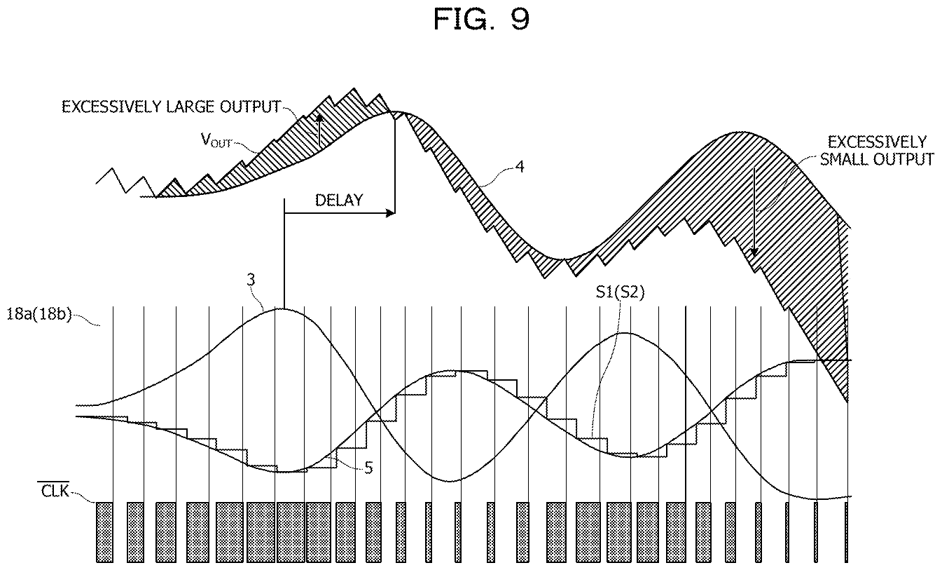

FIG. 9 is a diagram for describing the dead time adjustment function. For the input signal 3, the inversion signal 5 is generated by the waveform inversion circuit 44 that vertically inverts an input waveform. The first sample hold circuit 45 (FIG. 5) samples the inversion signal 5 according to the sampling signal 18a, and outputs the first quantization signal S1 which is a signal obtained by quantizing the inversion signal 5. The second sample hold circuit 46 (FIG. 5) samples the inversion signal 5 according to the delay sampling signal 18b, and outputs the second quantization signal S2 which is a signal obtained by quantizing the inversion signal 5.

By quantization of the inversion signal 5 in this manner, a value of the first quantization signal S1 and a value of the second quantization signal S2 decrease as the voltage of the input signal 3 increases. Therefore, as the voltage of the input signal 3 increases, the fifth delay circuit 39 (FIG. 5) may generate the first control voltage V(ΔT₁) that decreases the first delay amount ΔT₁ to a delay amount corresponding to the value of the first quantization signal S1. Similarly, as the voltage of the input signal 3 increases, the sixth delay circuit 40 (FIG. 5) may generate the second control voltage V(ΔT₂) that decreases the second delay amount ΔT₂ to a delay amount corresponding to the value of the second quantization signal S2.

Since the second delay circuit 41 (FIG. 5) delays the first pulse signal 49 by the first delay amount ΔT₁ corresponding to the first control voltage V(ΔT₁), the first dead time Td1 may be shortened as the voltage of the input signal 3 increases. For example, the first dead time Td1 becomes shorter as the first quantization signal S1 becomes larger. Similarly, since the third delay circuit 42 (FIG. 5) delays the second pulse signal 51 by the second delay amount ΔT₂ corresponding to the second control voltage V(ΔT₂), the second dead time Td2 may be shortened as the voltage of the input signal 3 increases. For example, the second dead time Td2 becomes shorter as the second quantization signal S2 becomes larger.

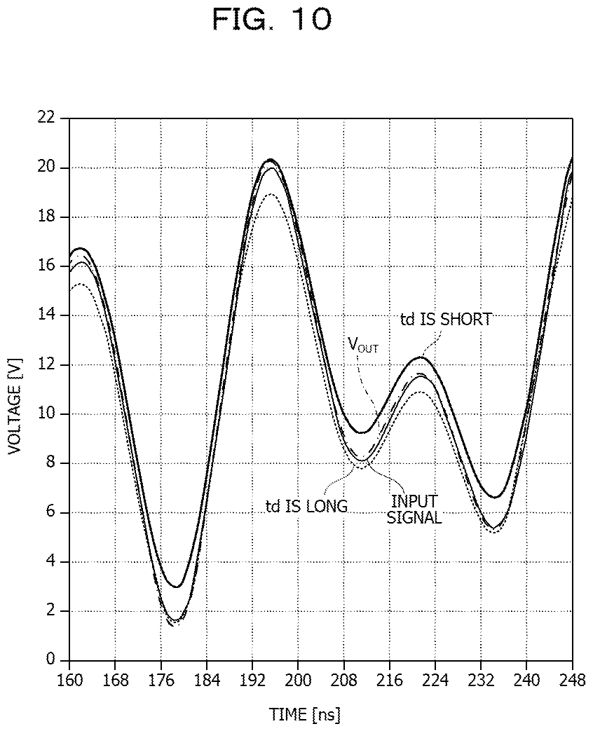

FIG. 10 is a diagram for describing an effect of the dead time adjustment function of shortening the dead time Td when the voltage of the input signal 3 is higher than the average voltage Va of the input signal 3 as compared with when the voltage of the input signal 3 is lower than the average voltage Va of the input signal 3. As illustrated in FIG. 10, the accuracy of causing the output voltage V_{OUT} to follow the voltage of the input signal 3 is improved.

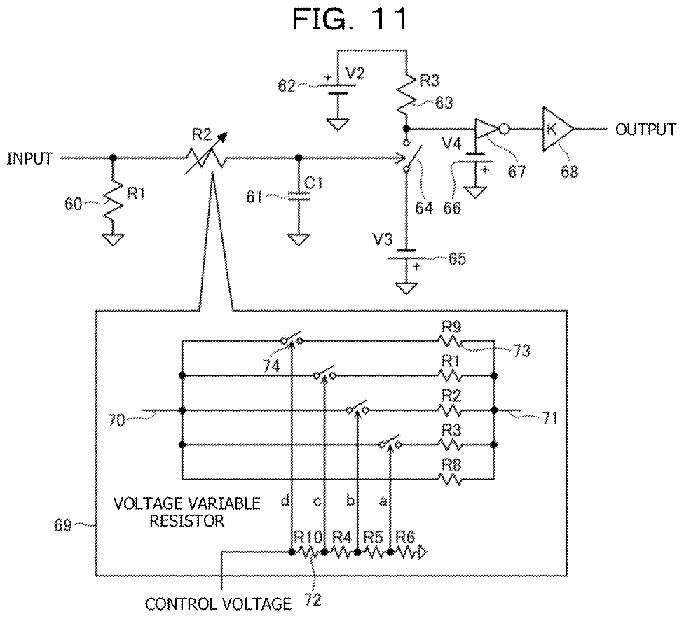

FIG. 11 is a configuration diagram of an example of the delay circuit. Each of the delay circuits described above (the first delay circuit 38, the second delay circuit 41, the third delay circuit 42, the fourth delay circuit 43, the fifth delay circuit 39, and the sixth delay circuit 40) has, for example, a configuration illustrated in FIG. 11.

The delay circuit includes a resistor 60, a voltage variable resistor 69, a capacitor 61, a direct current power supply 62, a resistor 63, a switch 64, a direct current power supply 65, an inversion circuit 67, a direct current power supply 66, and an amplifier 68. In order to stabilize a potential of an input terminal to which an input signal to be delayed is input, the resistor 60 is coupled between the input terminal and a ground. The resistor 60 has a resistance value R1. The voltage variable resistor 69 has a variable resistance value R2. The voltage variable resistor 69 and the capacitor 61 are CR filters that delay the input signal. The capacitor 61 has a capacitance C1. The switch 64 is turned on or off according to the delayed input signal. The direct current power supply 62, the resistor 63, and the switch 64 constitute a circuit for amplifying the delayed input signal. The direct current power supply 65 is a voltage source for adjusting a low level of the amplified input signal. The inversion circuit 67 inverts a level of the amplified input signal for output. The direct current power supply 66 is a voltage source for adjusting a low level of the inverted and output signal. The amplifier 68 amplifies the inverted and output signal to a desired signal level at an amplification factor K for output. The direct current power supplies 62, 65, and 66 generate constant voltages V2, V3, and V4, respectively.

The voltage variable resistor 69 has the resistance value R2 that changes according to a control voltage supplied from the outside, and determines a delay amount of the input signal according to the resistance value R2. The voltage variable resistor 69 includes an input terminal 70, an output terminal 71, a resistor group 72, a plurality of switches 74, and a plurality of resistors 73. The resistor group 72 includes resistors R6, R5, R4, and R10 that divide the control voltage supplied from the outside into a plurality of voltage values a, b, c, and d. The voltage variable resistor 69 has a configuration in which a plurality of series circuits of the switches 74 and the resistors are coupled in parallel between the input terminal 70 and the output terminal 71. The plurality of switches 74 is turned on or off according to the corresponding voltage values among the plurality of voltage values a, b, c, and d. The plurality of resistors 73 includes resistors R9, R1, R2, R3, and R8. Here, the number of parallels of the switches 74 and the resistors 73 is determined according to a needed delay time resolution.

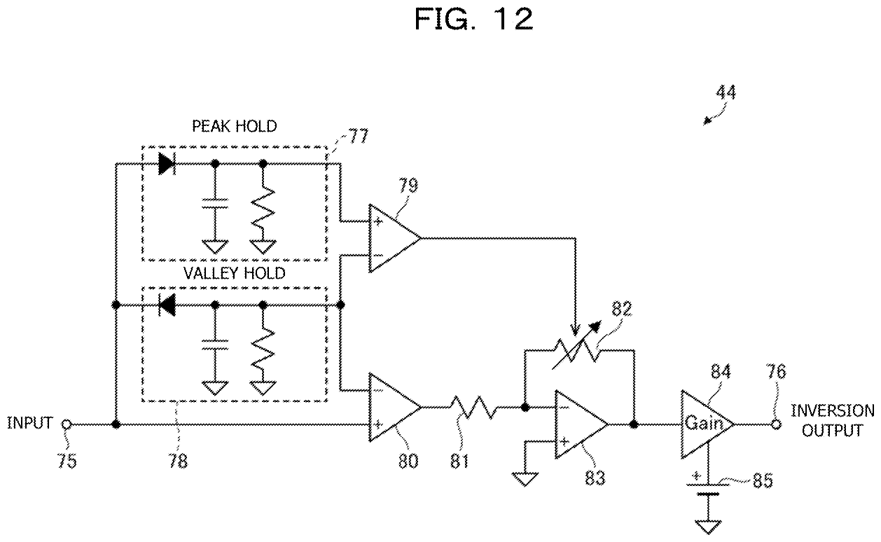

FIG. 12 is a configuration diagram of an example of the waveform inversion circuit. The waveform inversion circuit 44 described above has, for example, a configuration illustrated in FIG. 12. The waveform inversion circuit 44 includes an input terminal 75, an output terminal 76, a peak hold circuit 77, a valley hold circuit 78, differential amplifiers 79, 80, and 83, a resistor 81, a variable resistor 82, an amplifier 84, and a direct current voltage source 85.

An input signal to be subjected to waveform inversion processing is input from the input terminal 75. The peak hold circuit 77 holds a peak of the input signal from the input terminal 75 for output. The peak hold circuit 77 includes a diode having an anode coupled to the input terminal 75, a capacitor coupled between a cathode of the diode and a ground, and a resistor coupled between the cathode of the diode and the ground. The valley hold circuit 78 holds a valley of the input signal from the input terminal 75 for output. The valley hold circuit 78 includes a diode having a cathode coupled to the input terminal 75, a capacitor coupled between an anode of the diode and a ground, and a resistor coupled between the anode of the diode and the ground.

The differential amplifier 79 amplifies and outputs a difference signal between an output signal of the peak hold circuit 77 and an output signal of the valley hold circuit 78. The differential amplifier 80 amplifies and outputs a difference signal between the input signal and the output signal of the valley hold circuit 78. An output terminal of the differential amplifier 80 is coupled to an inversion input terminal of the differential amplifier 83 for inversion amplification and one end of the variable resistor 82 via the resistor 81. The variable resistor 82 is coupled between the inversion input terminal and the output terminal of the differential amplifier 83. The inversion input terminal of the differential amplifier 83 is coupled to a ground. A resistance value of the variable resistor 82 changes according to output of the differential amplifier 79. The amplifier 84 increases or decreases an output signal of the differential amplifier 83 for inversion amplification. The direct current voltage source 85 is a power supply for adjusting a low level of the output signal of the amplifier 84.

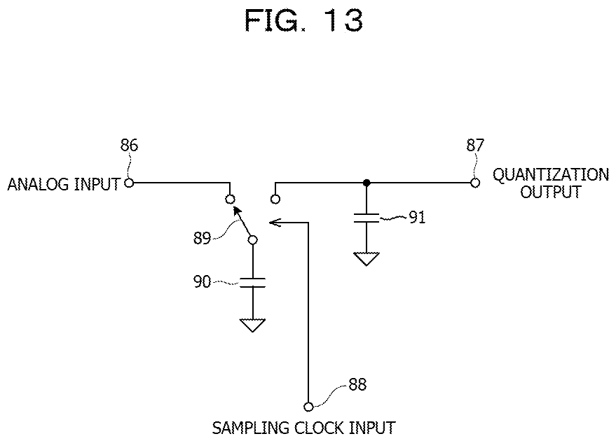

FIG. 13 is a configuration diagram of an example of the sample hold circuit. Each of the sample hold circuits described above (the first sample hold circuit 45 and the second sample hold circuit 46) has, for example, a configuration illustrated in FIG. 13.

The sample hold circuit includes an analog input terminal 86, a quantization output terminal 87, a clock input terminal 88, a switch 89, and capacitors 90 and 91. The analog input terminal 86 receives input of an analog signal (inversion signal 5 (FIG. 5)) to be sampled and held. The clock input terminal 88 receives input of the sampling signal 18a (delay sampling signal 18b). The switch 89 is a single-pole double-throw (SPDT) switch that switches a coupling destination of the capacitor 90 according to the sampling signal 18a (delay sampling signal 18b). The capacitor 90 temporarily holds a voltage of the analog inversion signal 5. The capacitor 91 receives and holds the transferred voltage temporarily held in the capacitor 90. The quantization output terminal 87 outputs the first quantization signal S1 (second quantization signal S2) corresponding to the voltage of the capacitor 91.

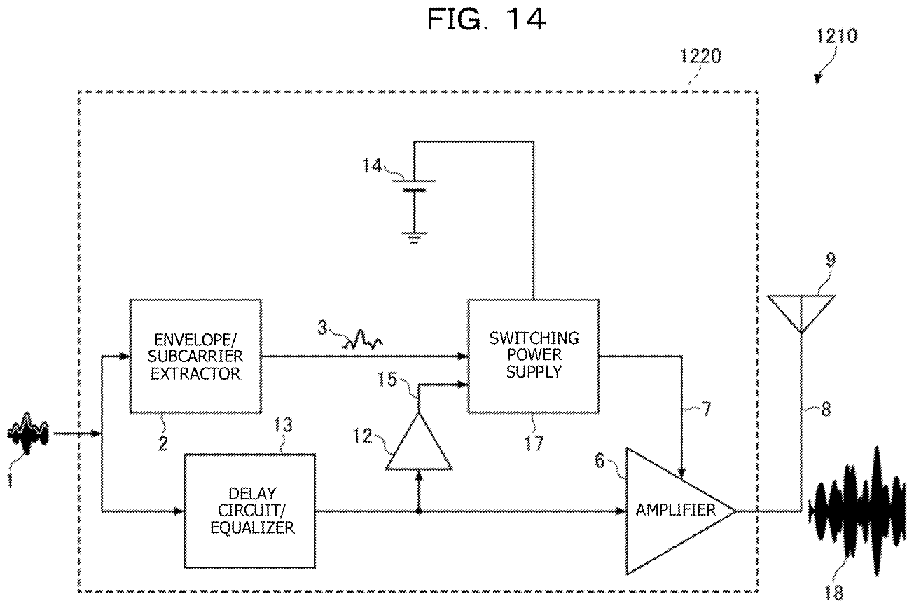

FIG. 14 is a diagram illustrating a configuration example of a communication device of a second embodiment. In the second embodiment, description of configurations, operation, and effects similar to those in the first embodiment will be omitted or simplified by referring to the description above. A communication device 1210 of the second embodiment is different from the communication device 1110 (FIG. 1) of the first embodiment in that a carrier amplifier 12 is included and a processing circuit 13 (delay circuit or equalizer) is included instead of the limiter 16. In FIG. 14, the communication device 1210 includes an amplification device 1220 and an antenna 9. The amplification device 1220 includes an extractor 2, a switching power supply 17, a constant voltage power supply 14, the processing circuit 13, the carrier amplifier 12, and a high-power amplifier 6.

The processing circuit 13 is a delay circuit that executes delay processing for delaying a modulated wave 1 or an equalizer that executes equalization processing for adjusting a frequency characteristic of the modulated wave 1. The high-power amplifier 6 amplifies and outputs the modulated wave 1 subjected to the delay processing or the equalization processing by the processing circuit 13. The carrier amplifier 12 extracts a carrier signal 15 from the modulated wave 1 subjected to the delay processing or the equalization processing by the processing circuit 13, and outputs the carrier signal 15. The carrier amplifier 12 only needs to be able to amplify the carrier signal 15 and output the carrier signal 15 having a desired amplitude. Note that the processing circuit 13 may be replaced with the limiter 16 described above.

The switching power supply 17 uses the carrier signal 15 as a sampling signal instead of the sampling signal 18a described above. In this case, a comparator 37 (FIG. 5) compares a delay input signal 4 with the carrier signal 15 and outputs a first pulse signal 49 which is a pulse width modulation signal.

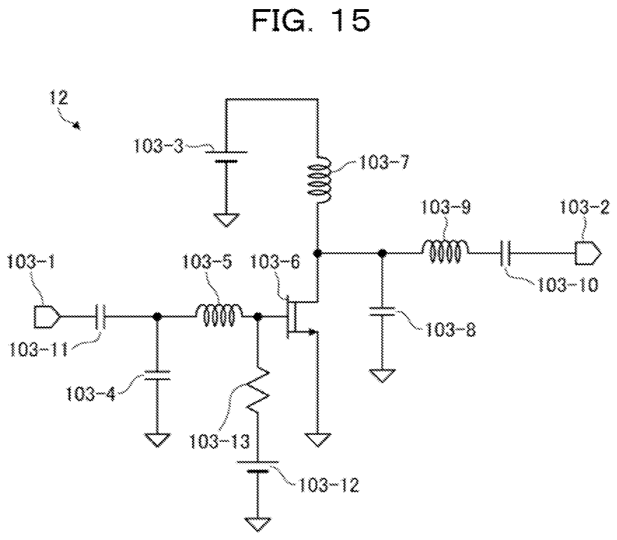

FIG. 15 is a configuration diagram of an example of the carrier amplifier. The carrier amplifier 12 includes an input terminal 103-1, an output terminal 103-2, a constant voltage source 103-3, a capacitor 103-11, a capacitor 103-4, and an inductor 103-5. Furthermore, the carrier amplifier 12 includes a resistor 103-13, a constant voltage source 103-12, a transistor 103-6, an inductor 103-7, a capacitor 103-8, an inductor 103-9, and a capacitor 103-10.

The input terminal 103-1 receives input of the modulated wave 1 processed by the processing circuit 13. The output terminal 103-2 outputs the carrier signal 15 included in the modulated wave 1. The constant voltage source 103-3 generates a constant voltage. The capacitor 103-11 blocks input of a direct current included in the modulated wave 1 processed by the processing circuit 13. The capacitor 103-4 and the inductor 103-5 are for a matching circuit that matches an input signal. The resistor 103-13 and the constant voltage source 103-12 are for a gate bias. The transistor 103-6 is for amplification of the input signal. The inductor 103-7 is for blocking an alternating current signal. The capacitor 103-8 and the inductor 103-9 are for a matching circuit that matches an output signal. The capacitor 103-10 blocks output of a direct current included in the carrier signal 15 output from the output terminal 103-2.

The transistor 103-6 for amplification is, for example, an element formed of a field effect transistor, for example, an element formed of a high electron mobility transistor (HEMT). When a maximum oscillation frequency fmax of the transistor 103-6 is about 5 times (for example, 4 times or more and 6 times or less) a carrier frequency, the carrier amplifier 12 having a sufficient gain may be obtained.

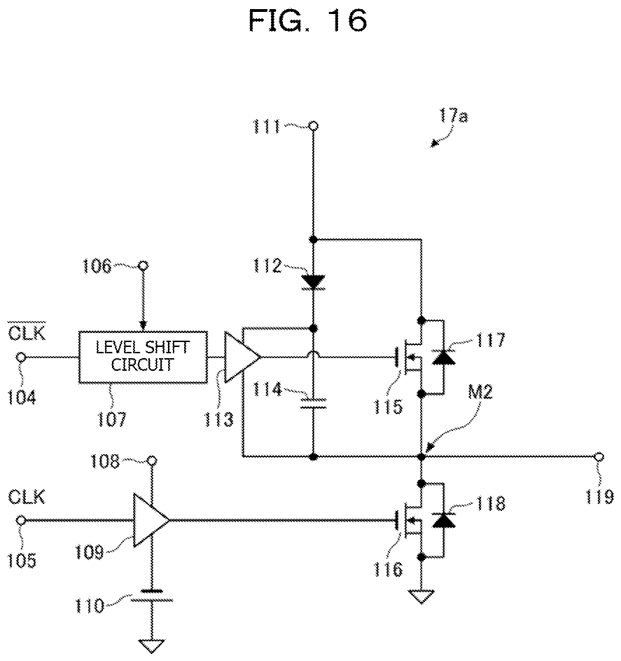

FIG. 16 is a configuration diagram of a switching power supply circuit in a case where switches SW1 and SW2 (FIG. 2) are implemented by transistors. FIG. 16 exemplifies a peripheral circuit for operating a transistor 115 corresponding to the switch SW1 and a transistor 116 corresponding to the switch SW2. The configuration of the peripheral circuit is not limited to this. Note that, in FIG. 16, illustration of an inductor 21 and a capacitor 22 is omitted.

In FIG. 16, a switching power supply circuit 17a includes an inversion clock input terminal 104, a clock input terminal 105, a level shift circuit 107, a control terminal 106, a driver amplifier 113, a capacitor 114, a diode 112, and a power supply terminal 111. Furthermore, the switching power supply circuit 17a includes the transistor 115, a diode 117, a driver amplifier 109, a power supply terminal 108, a constant voltage source 110, the transistor 116, a diode 118, and an output terminal 119.

The inversion clock input terminal 104 receives input of a clock CLKbar. The level shift circuit 107 converts an amplitude of the clock CLKbar into a voltage suitable for driving the transistor 115, and supplies the converted clock CLKbar to the driver amplifier 113. The control terminal 106 is a terminal to which a control voltage for controlling a potential of the level shift circuit 107 is input. The driver amplifier 113 is a gate driver that drives the transistor 115. The capacitor 114 is coupled between a positive power supply terminal and a negative power supply terminal of the driver amplifier 113. The diode 112 includes a cathode electrode coupled to the positive power supply terminal of the driver amplifier 113 and an anode electrode coupled to the power supply terminal 111 to which a constant power supply voltage V_{DC} is input. The capacitor 114 and the diode 112 function as a bootstrap circuit that generates a voltage of the positive power supply terminal of the driver amplifier 113. The transistor 115 is an N-channel metal oxide semiconductor field effect transistor (MOSFET). The diode 117 is coupled in antiparallel to the transistor 115.

The clock input terminal 105 receives input of a clock CLK. The driver amplifier 109 is a gate driver that amplifies the clock CLK and drives the transistor 116. The power supply terminal 108 receives input of the constant power supply voltage V_{DC} as a positive power supply voltage of the driver amplifier 109. The constant voltage source 110 generates a negative power supply voltage of the driver amplifier 109. The transistor 116 is an N-channel MOSFET. The diode 118 is coupled in antiparallel to the transistor 116. A node M2, which is a coupling point between the transistor 115 and the transistor 116, is coupled to the output terminal 119. The output terminal 119 is coupled to an LC circuit (the inductor 21 and the capacitor 22) illustrated in FIG. 2.

In FIG. 16, when a logic level of the clock CLK is a level at which the transistor 116 is turned on and a logic level of the clock CLKbar is a level at which the transistor 115 is turned off, a potential at the node M2 is at a low level. Thus, in the capacitor 114, a potential of one electrode coupled to the node M2 reaches a low level, and a potential of the other electrode coupled to the diode 112 instantaneously reaches a level equivalent to a low level because the capacitor 114 is not charged with charges. As a result, the capacitor 114 is charged by a constant voltage power supply coupled to the power supply terminal 111 through the diode 112, and a potential difference between both ends of the capacitor 114 becomes a value obtained by subtracting a forward voltage of the diode 112 from the constant power supply voltage V_{DC} of the constant voltage power supply. With this configuration, even when the transistor 116 transitions from an on state to an off state and the potential of the node M2 rises, a potential difference between the positive power supply terminal and the negative power supply terminal of the driver amplifier 113 is secured at a level sufficient to drive the transistor 115.

Next, when the clock CLK at a level at which the transistor 116 is turned off is input to the driver amplifier 109, output of the driver amplifier 109 transitions from on to off. With this configuration, the transistor 116 transitions from the on state to the off state, and both the transistor 115 and the transistor 116 go into the off state, so that a first dead time period starts. In the first dead time period, a return current flowing to the LC circuit (the inductor 21 and the capacitor 22) through the diode 118 and the output terminal 119 is generated.

Next, when the clock CLKbar at a level at which the transistor 115 is turned on is input to the driver amplifier 113 through the level shift circuit 107, the transistor 115 gate-driven by the driver amplifier 113 goes into the on state. With this configuration, a current flowing from the constant voltage power supply coupled to the power supply terminal 111 flows to the LC circuit (the inductor 21 and the capacitor 22) through the transistor 115 and the output terminal 119.

Next, when the clock CLKbar at a level at which the transistor 115 is turned off is input to the driver amplifier 113 through the level shift circuit 107, output of the driver amplifier 113 transitions from on to off. With this configuration, the transistor 115 transitions from the on state to the off state, and both the transistor 115 and the transistor 116 go into the off state, so that a second dead time period starts. In the second dead time period, a return current flowing to the LC circuit (the inductor 21 and the capacitor 22) through the diode 118 and the output terminal 119 is generated.

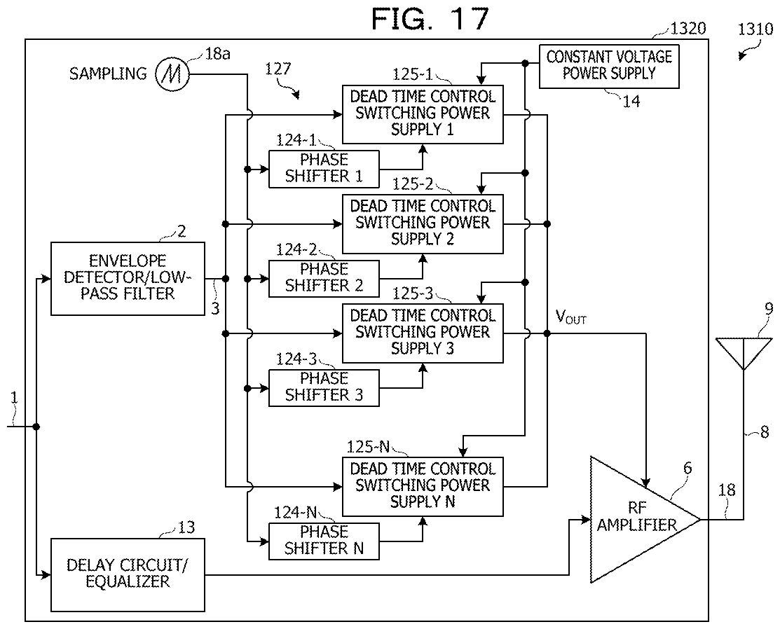

FIG. 17 is a diagram illustrating a configuration example of a communication device of a third embodiment. In the third embodiment, description of configurations, operation, and effects similar to those in the embodiments described above will be omitted or simplified by referring to the description above. A communication device 1310 of the third embodiment is different from the communication device 1110 (FIG. 1) of the first embodiment and the communication device 1210 (FIG. 14) of the second embodiment in that a plurality of switching power supplies coupled in parallel and a plurality of phase shifters to which a common sampling signal 18a is input are included. In FIG. 17, the communication device 1310 includes an amplification device 1320 and an antenna 9. The amplification device 1320 includes a switching power supply 127, an extractor 2, a constant voltage power supply 14, a processing circuit 13, and a high-power amplifier 6. The switching power supply 127 includes a plurality of switching power supplies 125-1, 125-2, 125-3, . . . , and 125-N and a plurality of phase shifters 124-1, 124-2, 124-3, . . . , and 124-N. N represents an integer of 2 or more.

The amplification device 1320 drives the plurality of switching power supplies coupled in parallel by using a plurality of sampling signals having different phases, and combines output of each of the switching power supplies to reduce a ripple voltage included in an output voltage of each of the switching power supplies.

Each of the plurality of switching power supplies 125-1 to 125-N is a power supply unit having the same configuration as that of the switching power supply 17 illustrated in FIG. 5. Each of the plurality of phase shifters 124-1 to 124-N generates a plurality of sampling signals having different phases from the common sampling signal 18a.

The plurality of sampling signals to which phases from 0 degrees to 360 degrees are equally distributed are generated by the plurality of phase shifters 124-1 to 124-N. For example, when N=4 is satisfied, four sampling signals whose phases are shifted by 0 degrees, 90 degrees, 180 degrees, and 270 degrees relative to the sampling signal 18a are generated by the four phase shifters 124-1 to 124-4.

Note that it is assumed that the number N of phase shifters is an even number, and the N phase shifters include at least two phase shifters that generate sampling signals having phase differences different from each other by 180 degrees. The phase shifters 124-1 to 124-N/2 generate at least one sampling signal having a phase of 0 degrees or more and less than 180 degrees, and the phase shifters 124-N/2+1 to 124-N generate at least one sampling signal having a phase of 180 degrees or more and less than 360 degrees.

A comparator 37 (FIG. 5) of each of the plurality of switching power supplies 125-1 to 125-N compares an input signal 3 with a corresponding sampling signal among the plurality of sampling signals having different phases, and outputs a first pulse signal 49 that is a pulse width modulation signal.

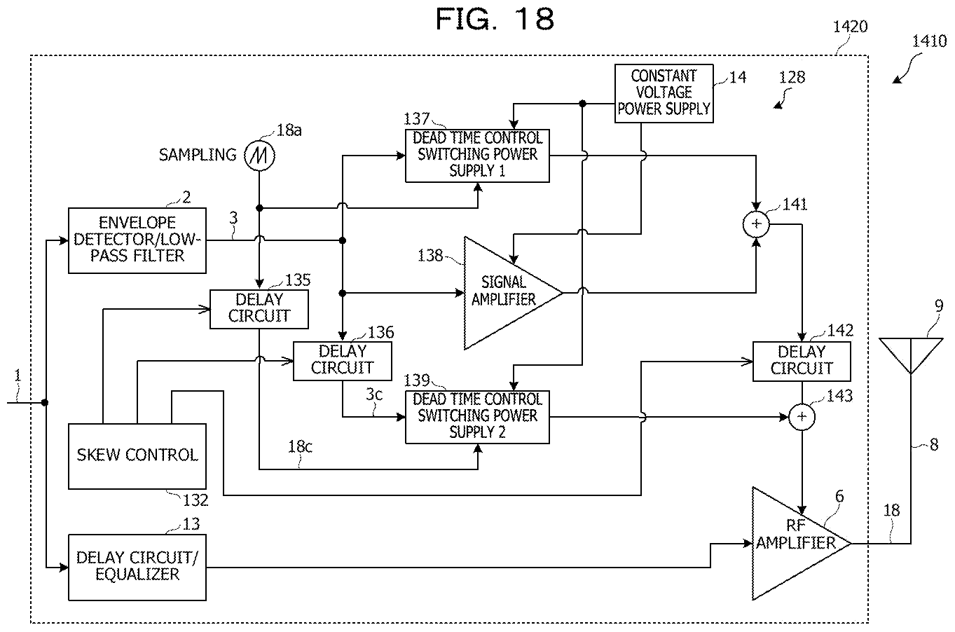

FIG. 18 is a diagram illustrating a configuration example of a communication device of a fourth embodiment. In the fourth embodiment, description of configurations, operation, and effects similar to those in the embodiments described above will be omitted or simplified by referring to the description above. A communication device 1410 of the fourth embodiment is different from the communication devices of the embodiments described above in that a plurality of switching power supplies 137 and 139, a seventh delay circuit 135, an eighth delay circuit 136, a signal amplifier 138, a first combiner 141, and a second combiner 143 are included. In FIG. 18, the communication device 1410 includes an amplification device 1420 and an antenna 9. The amplification device 1420 includes a switching power supply 128, an extractor 2, a constant voltage power supply 14, a processing circuit 13, and a high-power amplifier 6. The switching power supply 128 includes the plurality of switching power supplies 137 and 139, the seventh delay circuit 135, the eighth delay circuit 136, a ninth delay circuit 142, the signal amplifier 138, a skew controller 132, the first combiner 141, and the second combiner 143.

The amplification device 1420 extracts a difference signal between output of the switching power supply 137 for which dead time control is possible and output of the signal amplifier 138 capable of amplifying an input signal 3, combines the difference signal with output of the switching power supply 139 for which dead time control is possible for output. With this configuration, a ripple voltage included in an output voltage of each switching power supply is reduced.

The plurality of switching power supplies 137 is a first power supply unit having the same configuration as that of the switching power supply 17 illustrated in FIG. 5. The plurality of switching power supply 139 is a second power supply unit having the same configuration as that of the switching power supply 17 illustrated in FIG. 5. The skew controller 132 aligns operation timings of the seventh delay circuit 135, the eighth delay circuit 136, and the ninth delay circuit 142.

The switching power supply 137 outputs a voltage that changes in a waveform following the input signal 3 by the input signal 3 and a sampling signal 18a. The seventh delay circuit 135 outputs a second delay sampling signal 18c obtained by delaying the sampling signal 18a. The eighth delay circuit 136 outputs a second delay input signal 3c obtained by delaying the input signal 3. The switching power supply 139 outputs a voltage that changes in a waveform following the second delay input signal 3c by the second delay input signal 3c and the second delay sampling signal 18c. The signal amplifier 138 amplifies and outputs the input signal 3.

The first combiner 141 combines an output voltage of the switching power supply 137 to which the input signal 3 and the sampling signal 18a are input with an output voltage of the signal amplifier 138. A gain determining magnitude of the output voltage of the switching power supply 137 relative to the input signal 3, a gain of the signal amplifier 138, and a gain determining magnitude of an output voltage of the switching power supply 139 relative to the second delay input signal 3c are set to the same value with each other. Furthermore, in addition in the first combiner 141, a sign of the output voltage from the switching power supply 137 is set to positive, and a sign of the output voltage from the signal amplifier 138 is set to negative. By arranging an amplifier having a gain of −1 at an output unit of the signal amplifier 138, the first combiner 141 may perform addition processing using output of the amplifier as a positive sign.

The first combiner 141 outputs a difference signal between the output voltage from the switching power supply 137 and the output voltage from the signal amplifier 138. The difference signal is combined with the output voltage from the switching power supply 139 by the second combiner 143. At this time, the second combiner 143 performs the addition processing with a sign of the difference signal being positive and a sign of the output voltage from the switching power supply 139 being positive.

The difference signal between the output voltage from the switching power supply 137 and the output voltage from the signal amplifier 138 represents an insufficient or excessive component of the output voltage from the switching power supply 137. Therefore, the difference signal is added to the output voltage from the switching power supply 139 having the same configuration as that of the switching power supply 137, so that an output voltage of second combiner 143 follows the input signal 3 with high accuracy.

If output of the first combiner 141 is 0, the output voltage from the switching power supply 137 and the output voltage from the signal amplifier 138 completely match. Therefore, the second combiner 143 outputs only the output voltage from the switching power supply 139 having the same configuration as that of the switching power supply 137.

As described above, the embodiments have been described, but the embodiments described above are presented as examples, and the present disclosure is not limited by the embodiments described above. The embodiments described above may be implemented in various other forms, and various types of combination, omission, substitution, changes, and the like may be made without departing from the gist of the disclosure. These embodiments and modifications thereof are included in the scope and gist of the disclosure, and are included in the disclosure described in the claims and the equivalent scope thereof.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A switching power supply comprising:
a switching power supply circuit that has an upper arm and a lower arm that are coupled in series;
a drive circuit that alternately turns on the upper arm and the lower arm across a dead time in which the upper arm and the lower arm are turned off such that an output voltage of the switching power supply circuit follows a voltage of an input signal that is an envelope signal or a subcarrier signal; and
an adjustment circuit that adjusts the dead time according to the voltage of the input signal.

2. The switching power supply according to claim 1, wherein the adjustment circuit shortens the dead time when the voltage of the input signal is higher than an average voltage of the input signal as compared with when the voltage of the input signal is lower than the average voltage of the input signal.

3. The switching power supply according to claim 2, wherein the adjustment circuit generates an inversion signal that is a signal obtained by vertically inverting the input signal, generates a quantization signal that is a signal obtained by quantizing the inversion signal, and shortens the dead time as the quantization signal becomes larger.

4. The switching power supply according to claim 3, wherein
the drive circuit includes:
a first delay circuit that outputs a delay input signal that is a signal obtained by delaying the input signal;
a comparator that compares the delay input signal with a sampling signal and outputs a first pulse signal that is a pulse width modulation signal;
a second delay circuit that outputs a second pulse signal obtained by delaying the first pulse signal by a first delay amount that corresponds to a first control voltage, and switches the upper arm;
a third delay circuit that outputs a third pulse signal obtained by delaying the second pulse signal by a second delay amount that corresponds to a second control voltage; and
a negative OR circuit that outputs a fourth pulse signal that is a negative OR of the first pulse signal and the third pulse signal, and switches the lower arm, and
the adjustment circuit includes:
a fourth delay circuit that outputs a delay sampling signal that is a signal obtained by delaying the sampling signal;
a first sample hold circuit that samples the inversion signal according to the sampling signal and outputs a first quantization signal;
a second sample hold circuit that samples the inversion signal according to the delay sampling signal and outputs a second quantization signal;
a fifth delay circuit that delays the first quantization signal and outputs the first control voltage; and
a sixth delay circuit that delays the second quantization signal and outputs the second control voltage.

5. The switching power supply according to claim 4, further comprising a skew controller that aligns operation timings of the first delay circuit, the fourth delay circuit, the fifth delay circuit, and the sixth delay circuit.

6. The switching power supply according to claim 2, wherein, when the voltage of the input signal is higher than the average voltage of the input signal, the adjustment circuit shortens the dead time as the voltage of the input signal is higher, and when the voltage of the input signal is lower than the average voltage of the input signal, the adjustment circuit lengthens the dead time as the voltage of the input signal is lower.

7. The switching power supply according to claim 1, further comprising:
a plurality of power supply units each of which includes the switching power supply circuit, the drive circuit, and the adjustment circuit; and
a plurality of phase shifters that generates a plurality of sampling signals that has different phases, wherein
the drive circuit includes a comparator that compares the input signal with a corresponding sampling signal among the plurality of sampling signals and outputs a first pulse signal that is a pulse width modulation signal.

8. The switching power supply according to claim 1, further comprising:
a first power supply unit that includes the switching power supply circuit, the drive circuit, and the adjustment circuit;
a second power supply unit that includes the switching power supply circuit, the drive circuit, and the adjustment circuit;
a seventh delay circuit that outputs a second delay sampling signal obtained by delaying a sampling signal;
an eighth delay circuit that outputs a second delay input signal obtained by delaying the input signal;
a signal amplifier that amplifies the input signal;
a first combiner that combines the output voltage of the first power supply unit to which the input signal and the sampling signal are input with an output voltage of the signal amplifier; and
a second combiner that combines the output voltage of the second power supply unit to which the second delay input signal and the second delay sampling signal are input with an output voltage of the first combiner.

9. The switching power supply according to claim 4,
wherein the input signal is an envelope signal or a subcarrier signal.

10. An amplification device comprising:
an extractor that extracts an input signal that is an envelope signal or a subcarrier signal from a modulated wave;
an amplifier that amplifies the modulated wave;
a switching power supply circuit that has an upper arm and a lower arm that are coupled in series and generates an output voltage that is a power supply voltage of the amplifier;
a drive circuit that alternately turns on the upper arm and the lower arm across a dead time in which the upper arm and the lower arm are turned off such that the output voltage follows a voltage of the input signal; and
an adjustment circuit that adjusts the dead time according to the voltage of the input signal.

11. The amplification device according to claim 10, further comprising:
a processing circuit that delays or equalizes the modulated wave; and
a carrier amplifier that extracts a carrier signal from the modulated wave subjected to delay processing or equalization processing by the processing circuit, wherein the drive circuit includes a comparator that compares the input signal with the carrier signal and outputs a first pulse signal that is a pulse width modulation signal.

12. A communication device comprising:
an extractor that extracts an input signal that is an envelope signal or a subcarrier signal from a modulated wave;
an amplifier that amplifies the modulated wave;
an antenna fed by the amplifier;
a switching power supply circuit that has an upper arm and a lower arm that are coupled in series and generates an output voltage that is a power supply voltage of the amplifier;
a drive circuit that alternately turns on the upper arm and the lower arm across a dead time in which the upper arm and the lower arm are turned off such that the output voltage follows a voltage of the input signal that is the envelope signal or the subcarrier signal; and
an adjustment circuit that adjusts the dead time according to the voltage of the input signal.
